(19) United States
(12) Patent Application Publication
(10) Pub. No.: US 2021/0214608 A1
(43) Pub. Date: Jul. 15, 2021

(54) STABLE QUANTUM DOT EXTRUSION FILM

(71) Applicant: SHPP Global Technologies B.V., Bergen op Zoom (NL)

(72) Inventors: Soonyoung HYUN, Gyeonggi-do (KR); Jong Woo LEE, Seoul (KR); Adel Fawzy BASTAWROS, Newburgh, IN (US); Hao ZHOU, Newburgh, IN (US)

(21) Appl. No.: 16/637,348

(22) PCT Filed: Aug. 7, 2018
(86) PCT No.: PCT/US2018/045598

§ 371 Date: Feb. 7, 2020

Related U.S. Application Data
(63) Continuation-in-part of application No. 15/670,416, filed on Aug. 7, 2017, now abandoned.

(51) Int. Cl. C09K 11/56; H01L 33/50; B29C 48/18

(52) U.S. Cl. CPC C09K 11/565; B82Y 20/00; B29C 48/18; H01L 33/502

(57) ABSTRACT

A quantum dot film includes at least one extruded polymer layer, the at least one extruded polymer layer including a plurality of stabilized quantum dots. The stabilized quantum dots may include one or more of the following: an encapsulation around each of the plurality of stabilized quantum dots, the encapsulation including an organic material or an inorganic material; a plurality of ligands having a length of about 5 nanometers (nm) to about 200 nm; a multi-shell structure; a shell having a thickness of about 1 to about 20 nm; and a concentration-gradient quantum dot.

### FIELD OF THE DISCLOSURE

The present disclosure relates to extruded films including quantum dots, and more particularly to extruded films including stabilized quantum dots that maintain their optical properties when extruded.

### BACKGROUND OF THE DISCLOSURE

Conventional quantum dot (QD) films include a quantum dot layer located between two barrier film layers. An exemplary conventional QD film 100 is illustrated in FIG. 1, which includes the quantum dot layer 110 including a plurality of quantum dots, which can include, for example, red quantum dots 120 and green quantum dots 130. A barrier film layer 140 on each side of the quantum dot layer 110 includes an inorganic barrier layer 150 and a substrate 160 (such as polyethylene terephthalate). The barrier film layer 140 may optionally include an adhesive/top coating layer 170 that provides for adhesion between the quantum dot layer 110 and the barrier film layer 140, and a diffuser layer 180 that can include texturing features. Each of the numerous layers in the conventional QD film 100 typically have a different refractive index, which results in a substantial loss of optical properties of the plurality of quantum dots 120, 130 in the quantum dot layer 110.

The barrier film layers 140 protect the quantum dots 120, 130, which can be easily damaged by exposure to oxygen and moisture. The first (bottom) barrier film layer 140 is typically formed using techniques employed in the film metallizing art such as sputtering, evaporation, chemical vapor deposition, plasma deposition, atomic layer deposition, plating and the like. The second (top) barrier film layer 140 is laminated onto the quantum dot layer 110. Each barrier film layer 140 must be thick enough to prevent wrinkling in roll-to-roll or laminate manufacturing processes, increasing the cost of the QD film 100 and adversely affecting the optical properties of the quantum dots 120, 130. Conventional barrier film materials include polyethylene terephthalate (PET) and oxides such as silicon oxides, metal oxides, metal nitrides, metal carbides, and metal oxynitrides.

Barrier film materials are also more expensive than standard film materials. As a result, the cost of QD films is high, and they cannot readily be adapted to mobile applications because the thickness of the barrier films makes it difficult to reduce the thickness of the QD film below 100 micrometers (μm). Further, the optical light path for the QD film is longer when barrier films are included because the transparency of the barrier film is no greater than about 93% (between 430 and 650 nanometers (nm)), which results in a reduction in optical properties such as quantum yield (QY) and luminance. Reducing QD film thickness would provide design freedom to mobile and tablet manufacturers, who could use the space that is gained to provide other functionalities and/or increase battery capacity.

These and other shortcomings are addressed by aspects of the present disclosure.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document.

FIG. 1 is a side view of a prior art quantum dot film.

FIGS. 2A and 2B are side views of quantum dot films according to aspects of the disclosure.

FIGS. 3A and 3B are side views of quantum dot films according to aspects of the disclosure.

FIGS. 4A to 4D are side views of quantum dot films according to aspects of the disclosure.

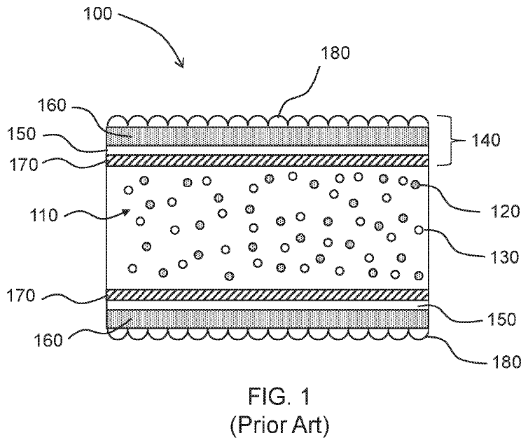

### SUMMARY

Aspects of the disclosure relate to a quantum dot film including at least one extruded polymer layer, the at least one extruded polymer layer including a plurality of stabilized quantum dots. The stabilized quantum dots may include one or more of the following: an encapsulation around each of the plurality of stabilized quantum dots, the encapsulation including an organic material or an inorganic material; a plurality of ligands having a length of about 5 nanometers (nm) to about 200 nm; a multi-shell structure; a shell having a thickness of about 1 to about 20 nm; and a concentration-gradient quantum dot.

Aspects of the disclosure further relate to a method of making a quantum dot film, the method including extruding at least one polymer layer into a film. The at least one polymer layer includes a plurality of stabilized quantum dots including one or more of the following: an encapsulation around each of the plurality of stabilized quantum dots, the encapsulation including an organic material or an inorganic material; a plurality of ligands having a length of about 5 nanometers (nm) to about 200 nm; a multi-shell structure; a shell having a thickness of about 1 to about 20 nm; and a concentration-gradient quantum dot.

### DETAILED DESCRIPTION

The present disclosure can be understood more readily by reference to the following detailed description of the disclosure and the Examples included therein. In various aspects, the present disclosure pertains to a quantum dot film including at least one extruded polymer layer, the at least one extruded polymer layer including a plurality of stabilized quantum dots. The stabilized quantum dots may include one or more of the following:

an encapsulation around each of the plurality of stabilized quantum dots, the encapsulation including an organic material or an inorganic material;

a plurality of ligands having a length of about 5 nanometers (nm) to about 200 nm;

a multi-shell structure;

a shell having a thickness of about 1 to about 20 nm; and

a concentration-gradient quantum dot.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting.

Various combinations of elements of this disclosure are encompassed by this disclosure, e.g., combinations of elements from dependent claims that depend upon the same independent claim.

Moreover, it is to be understood that unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; and the number or type of aspects described in the specification.

All publications mentioned herein are incorporated herein by reference to disclose and describe the methods and/or materials in connection with which the publications are cited.

### Definitions

It is also to be understood that the terminology used herein is for the purpose of describing particular aspects only and is not intended to be limiting. As used in the specification and in the claims, the term “comprising” can include the embodiments “consisting of” and “consisting essentially of” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural referents unless the context clearly dictates otherwise. Thus, for example, reference to a mixture including “a quantum dot” includes mixtures of two or more quantum dots.

As used herein, the term “combination” is inclusive of blends, mixtures, alloys, reaction products, and the like.

Ranges can be expressed herein as from one value (first value) to another value (second value). When such a range is expressed, the range includes in some aspects one or both of the first value and the second value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the designated value, approximately the designated value, or about the same as the designated value. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

As used herein, the terms “optional” or “optionally” means that the subsequently described event or circumstance can or cannot occur, and that the description includes instances where said event or circumstance occurs and instances where it does not. For example, the phrase “optional additional additives” means that the additional additives can or cannot be included and that the description includes compositions that both include and do not include additional additives.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

References in the specification and concluding claims to parts by weight of a particular element or component in a composition or article, denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent of a component, unless specifically stated to the contrary, is based on the total weight of the formulation or composition in which the component is included.

As used herein the terms “weight percent,” “wt %,” and “wt. %,” which can be used interchangeably, indicate the percent by weight of a given component based on the total weight of the composition, unless otherwise specified. That is, unless otherwise specified, all wt % values are based on the total weight of the composition. It should be understood that the sum of wt % values for all components in a disclosed composition or formulation are equal to 100.

Unless otherwise stated to the contrary herein, all test standards are the most recent standard in effect at the time of filing this application.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions and it is understood that there are a variety of structures that can perform the same function that are related to the disclosed structures, and that these structures will typically achieve the same result.

### Quantum Dot Films

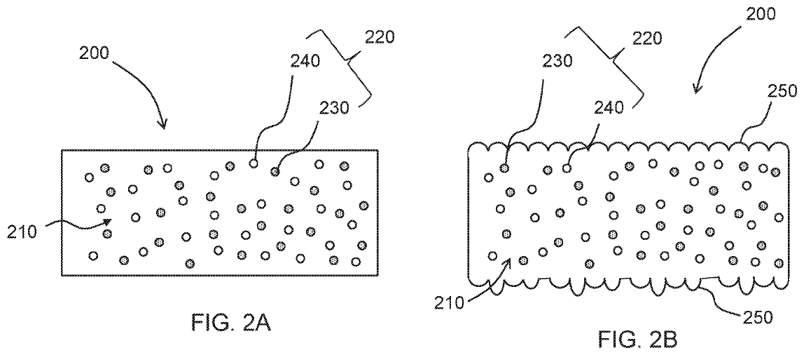

With reference to FIG. 2A, aspects of the disclosure relate to a quantum dot film 200 including at least one extruded polymer layer 210, the at least one extruded polymer layer 210 including a plurality of stabilized quantum dots 220. In some aspects, the plurality of stabilized quantum dots include red quantum dots 230 and green quantum dots 240. The quantum dot film 200 may optionally include texturing 250 on one or both surfaces of the quantum dot film 200 as illustrated in FIG. 2B.

In some aspects, the plurality of stabilized quantum dots 220 are thermally stabilized, air stabilized, moisture stabilized and/or flux stabilized, as described in further detail herein. The inclusion of stabilized quantum dots in the quantum dot film 200 allows the barrier layer(s) (protective layers) found in conventional quantum dot films to be eliminated, resulting in a quantum dot film that has improved optical properties as compared to conventional quantum dot films that include one or more barrier layers. In addition, elimination of the barrier layer(s) allows for formation and use of a thinner quantum dot film. Thinner quantum dot films are more useful in various applications, including display applications as discussed further herein.

The plurality of stabilized quantum dots 220 may be stabilized in any suitable manner. In some aspects, the plurality of stabilized quantum dots 220 are stabilized by providing an encapsulation around each of the plurality of stabilized quantum dots. The encapsulation may include an organic material or an inorganic material. The encapsulation protects the stabilized quantum dot from damage in the same manner that a barrier layer(s) would protect the quantum dot layer in a conventional quantum dot film.

The organic material may comprise a material that is chemically compatible with the QD ligand. In some examples, the organic material may comprise acrylate, epoxy, the group consisting of polyesters, poly(orthoester)s, polyanhydrides, poly(amino acid)s, poly(pseudo amino acid)s, and polyphosphazenes, the group consisting of poly(lactic acid)s, poly(glycolic acid)s, copolymers of lactic and glycolic acid, copolymers of lactic and glycolic acid with poly(ethylene glycol), poly(ε-caprolactone)s, poly(3-hydroxybutyrate)s, polybutyrolactones, polypropiolactones, poly(p-dioxanone)s, poly(valerolactone)s, poly(hydrovalerate)s, poly(propylene fumarate)s, dimethylpolysiloxane (PDMS). The inorganic material may comprise metal oxides, including, but not limited to silicon dioxide, titanium dioxide, and aluminum oxide. In certain aspects, each of the plurality of stabilized quantum dots 220 includes a plurality of ligands. The plurality of ligands may have a length of about 5 nanometers (nm) to about 200 nm. The plurality of ligands may include any ligand type that will interact (for example, attach) to the quantum dot. The plurality of ligands protect the quantum dot from damage. The ligand may be characterized by the formula

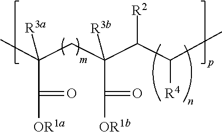

wherein each R^{1a}, R^{1b}, R² and R⁴ is independently selected from the group consisting of H, C₁₋₂₀ alkyl, C₁₋₂₀ heteroalkyl, C₂₋₂₀ alkenyl, C₂₋₂₀ alkynyl, cycloalkyl and aryl; each R^{3a} and R^{3b} is independently selected from the group consisting of H and C₁₋₆ alkyl; subscripts m and n are each independently 0 or 1, such that m+n is 1; and subscript p is an integer of from 5 to about 500, wherein when subscript m is 0, then at least one of R^{1a} and R^{1b} is H, and R² is selected from the group consisting of C₈₋₂₀ alkyl, C₈₋₂₀ heteroalkyl, C₈₋₂₀ alkenyl, C₈₋₂₀ alkynyl, cycloalkyl and aryl, and when subscript m is 1, then R^{1a} and R² are both H and R^{1b} is selected from the group consisting of C₈₋₂₀ alkyl, C₈₋₂₀ heteroalkyl, C₈₋₂₀ alkenyl, C₈₋₂₀ alkynyl, cycloalkyl and aryl. Suitable ligands may include, for example but are not limited to, oleic acid, trioctylphosphineoxide (TOPO) and trioctylphosphine (TOP).

In further examples, the quantum dot ligand may comprise a siloxane polymer comprising a plurality of monomer repeat units; a plurality of amine or carboxy binding groups each covalently attached to one of the monomer repeat units, thereby forming a first population of monomer repeat units; and a plurality of solubilizing groups each covalently attached to one of the monomer repeat units, thereby forming a second population of monomer repeat units. Suitable ligands may include, for example but are not limited to, dedecanoic acid, tetradecylphosphonic acid, 9-octadecenoic acid.

In further aspects, each of the plurality of stabilized quantum dots include a shell having a thickness of about 1 nm to about 20 nm. In other aspects each of the plurality of quantum dots include a multi-shell structure, such as but not limited to a first shell including a first material and at least a second shell including a second material that may be the same or different than the first material. The plurality of stabilized quantum dots in these aspects may have a core that is of the same or a different material than the shell or multi-shell structure material(s).

In yet further aspects each of the plurality of stabilized quantum dots include a concentration-gradient quantum dot. A concentration-gradient quantum dot includes an alloy of at least two semiconductors. The concentration (molar ratio) of the first semiconductor gradually increases from the core of the quantum dot to the outer surface of the quantum dot, and the concentration (molar ratio) of the second semiconductor gradually decreases from the core of the quantum dot to the outer surface of the quantum dot. Exemplary concentration-gradient quantum dots are described in, for example, U.S. Pat. No. 7,981,667, the disclosure of which is incorporated herein by this reference in its entirety.

In one aspect, the concentration-gradient quantum dot includes two semiconductors, a first semiconductor having the formula

CdₓZn₁₋ₓS_{y}Se_{1-y}

and having a maximum molar ratio at the core of the stabilized quantum dot that gradually decreases to a minimum molar ratio at the outer surface of the quantum dot and a second semiconductor having the formula

Zn_{z}Se_{1-z}S_{w}Se_{1-w}

and having a maximum molar ratio at the outer surface of the stabilized quantum dot that gradually decreases to a minimum molar ratio at the core of the stabilized quantum dot.

In another aspect, the concentration-gradient quantum dot includes two semiconductors, a first semiconductor having the formula

CdZnₓS₁₋ₓ

and having a maximum molar ratio at the core of the stabilized quantum dot that gradually decreases to a minimum molar ratio at the outer surface of the quantum dot and a second semiconductor having the formula

ZnCd_{z}S_{1-z}

and having a maximum molar ratio at the outer surface of the stabilized quantum dot that gradually decreases to a minimum molar ratio at the core of the stabilized quantum dot.

Exemplary quantum dots according to aspects of the disclosure may include, but are not limited to, semiconductor nanocrystals selected from the group consisting of, but not limited to, Group II-VI semiconductor compounds, Group II-V semiconductor compounds, Group III-VI semiconductor compounds, Group III-V semiconductor compounds, Group IV-VI semiconductor compounds, Group compounds, Group II-IV-VI compounds, Group II-IV-V compounds, alloys thereof and combinations thereof.

Exemplary Group II elements include zinc Zn, cadmium Cd, or mercury Hg or a combination thereof.

Exemplary Group III elements include aluminum Al, gallium Ga, indium In, titanium Ti or a combination thereof.

Exemplary Group IV elements include silicon Si, germanium Ge, tin Sn, lead Pb or a combination thereof.

Exemplary Group V elements include phosphorus P, arsenic As, antimony Sb, bismuth Bi or a combination thereof.

Exemplary Group VI elements include oxygen O, sulfur S, selenide Se, telluride Te or a combination thereof.

Exemplary Group II-VI semiconductor compounds include binary compounds, e.g., cadmium selenide CdSe, cadmium telluride CdTe, zinc sulfide ZnS, zinc selenide ZnSe, zinc telluride ZnTe, zinc oxide ZnO, mercury sulfide HgS, mercury selenide HgSe and mercury selenide HgTe; ternary compounds, e.g., zinc selenide sulfide CdSeS, cadmium selenide telluride CdSeTe, cadmium sulfide telluride CdSTe, zinc selenide sulfide ZnSeS, zinc selenide telluride ZnSeTe, zinc sulfide telluride ZnSTe, mercury selenide sulfide HgSeS, mercury selenide telluride HgSeTe, mercury sulfide telluride HgSTe, cadmium zinc sulfide CdZnS, cadmium zinc selenide CdZnSe, cadmium zinc telluride CdZnTe, cadmium mercury sulfide CdHgS, cadmium mercury selenide CdHgSe, cadmium mercury telluride CdHgTe, mercury zinc sulfide HgZnS and mercury zinc selenide HgZnSe; and quaternary compounds, e.g., cadmium zinc selenide sulfide CdZnSeS, cadmium zinc selenide telluride CdZnSeTe, cadmium zinc sulfide telluride CdZnSTe, cadmium mercury selenide sulfide CdHgSeS, cadmium mercury selenide telluride CdHgSeTe, cadmium mercury sulfide telluride CdHgSTe, mercury zinc selenide sulfide HgZnSeS, mercury zinc selenide telluride HgZnSeTe and mercury zinc sulfide telluride HgZnSTe.

Exemplary Group III-V semiconductor compounds include binary compounds, e.g., GaN, GaP, GaAs, GaSb, AlN, AlP, AlAs, AlSb, InN, InP, InAs and InSb; ternary compounds, e.g., GaNP, GaNAs, GaNSb, GaPAs, GaPSb, AlNP, AlNAs, AlNSb, AlPAs, AlPSb, InNP, InNAs, InN Sb, InPAs, InPSb, GaAlNP, AlGaN, AlGaP, AlGaAs, AlGaSb, InGaN, InGaP, InGaAs, InGaSb, AlInN, AlInP, AlInAs and AlInSb; and quaternary compounds, e.g., GaAlNAs, GaAlNSb, GaAlPAs, GaAlPSb, GaInNP, GaIn, NAs, GaInNSb, GaInPAs, GaInPSb, InAlNP, InAlNAs, InAlNSb, InAlPAs and InAlPSb.

Exemplary Group IV-VI semiconductor compounds include binary compounds, e.g., SnS, SnSe, SnTe, PbS, PbSe and PbTe; ternary compounds, e.g., SnSeS, SnSeTe, SnSTe, PbSeS, PbSeTe, PbSTe, SnPbS, SnPbSe and SnPbTe; and quaternary compounds, e.g., SnPbSSe, SnPbSeTe and SnPbSTe.

Exemplary Group IV semiconductor compounds include unary compounds, e.g., Si and Ge; and binary compounds, e.g., SiC and SiGe.

Where the plurality of stabilized quantum dots 220 are described herein as having a shell or a multi-shell structure (i.e., a core and at least one shell), the core and the shell or plurality of shells may independently be formed of the semiconductor materials described above.

The semiconductor nanocrystals may have a multilayer structure consisting of two or more layers composed of different materials. The multilayer structure of the semiconductor nanocrystals may include at least one alloy interlayer composed of two or more different materials at the interface between the adjacent layers. In one exemplary aspect, the alloy interlayer may be composed of an alloy having a composition gradient.

In yet other aspects, the plurality of stabilized quantum dots including quantum dots stabilized by a combination of two or more of these features.

In some aspects one or more of the plurality of stabilized quantum dots 220 is a metal nanomaterial or an inorganic nanomaterial. The form of the plurality of stabilized quantum dots 220 may include in certain aspects a nanoparticle, a nanofiber, a nanorod, or a nanowire.

The plurality of stabilized quantum dots 220 may have a size of from about 1 nanometer (nm) to about 100 nm in some aspects, or of from about 1 nm to about 50 nm in particular aspects.

The at least one extruded polymer layer 210 may include any polymer suitable for use in quantum dot films, and may include any thermoplastic polymer capable of being extruded as a polymer layer. Exemplary polymers that may be used in the at least one extruded polymer layer 210 include, but are not limited to, polycarbonate (PC), polyethylene terephthalate (PET), polymethyl methacrylate (PMMA), polyaryletherketones (PAEK), polybutylene terephthalate (PBT), cyclic olefin copolymer (COC), polyethylene naphthalate (PEN), poly(ether sulfone) PES, polyamide (PA), polyphthalamide (PPA), polyimides, polyolefins, polystyrene, and combinations thereof.

In some aspects the at least one extruded polymer layer 210 includes a scattering material. Scattering materials, which may include but are not limited to metal oxide particles, may be included in the at least one extruded polymer layer to modify the optical properties of the at least one extruded polymer layer 210 as desired. In further aspects, a separate layer including a scattering material (not illustrated) may be included in the quantum dot film 200. Exemplary scattering materials include, but are not limited to, titanium dioxide (TiO₂), silicon dioxide (SiO₂), aluminum oxide (Al₂O₃), zinc oxide (ZnO), zinc peroxide (ZnO₂), zirconium dioxide (ZrO₂), and combinations thereof. The scattering material in some aspects has a particle size of from about 0.1 micrometer (μm) to about 10 μm.

The at least one extruded polymer layer may in particular aspects include one or more optional additional additives, including but not limited to a dispersant, a scavenger, a stabilizer or a combination thereof. In particular, a scavenger may be provided to absorb oxygen and/or moisture, which could help to protect the stabilized quantum dot from damage in the presence thereof. Exemplary scavenger materials include, but are not limited to, oxygen scavengers such as hydrazine, Carbo-Hz, sodium sulfite, n,n-diethylhydroxylamine (DEHA), methylethyl ketone oxime (MEKO), erythorbate, hydroquinone, and combinations thereof, and moisture scavengers such as calcium oxide, magnesium oxide, strontium oxide, barium oxide, aluminum oxide, silicone oxide, and combinations thereof. The scavenger in some aspects has a particle size of from about 0.1 micrometer (μm) to about 10 μm.

### Methods of Making Quantum Dot Film

In certain aspects the at least one extruded polymer layer 210 is formed by an extrusion process. This is in contrast to conventional quantum dot films that do not include stabilized quantum dots and that cannot be extruded because the quantum dots used in conventional quantum dot films would be damaged or destroyed by the thermal and mechanical stresses that are inherent to the extrusion process. The use of stabilized quantum dots in aspects of the disclosure enable extrusion processes for making the quantum dot films described herein. Extrusion offers a low-cost method for making high performance quantum dot films.

In such an extrusion process the one or any foregoing components described herein (including the stabilized quantum dots) may first be dry blended together, then fed into an extruder from one or multi-feeders, or separately fed into an extruder from one or multi-feeders. The one or any foregoing components may be first dry blended with each other, or dry blended with any combination of foregoing components, then fed into an extruder from one or multi-feeders, or separately fed into an extruder from one or multi-feeders. The components may be fed into the extruder from a throat hopper or any side feeders.

In some aspects one or any foregoing components described herein (including the stabilized quantum dots) may, prior to extrusion, be prepared as a quantum dot formulation, or quantum dot “ink.” The quantum dot formulation may include the stabilized quantum dot particles and optional components including but not limited to a scattering material, a dispersant, a binder, a scavenger, a stabilizer and a combination thereof. The quantum dot formulation could be added to polymer and then fed into the extruder as described herein.

The extruders may have a single screw, multiple screws, intermeshing co-rotating or counter rotating screws, non-intermeshing co-rotating or counter rotating screws, reciprocating screws, conical screws, screws with pins, screws with screens, barrels with pins, rolls, rams, helical rotors, co-kneaders, disc-pack processors, various other types of extrusion equipment, or combinations comprising at least one of the foregoing.

The barrel temperature on the extruder during compounding can be set at the temperature where at least a portion of the polymer in the at least one extruded polymer layer has reached a temperature greater than or equal to about the melting temperature, if the polymer is a semi-crystalline organic polymer, or the flow point (e.g., the glass transition temperature) if the polymer is an amorphous polymer.

The mixture including the foregoing mentioned components may be subject to multiple blending and forming steps if desirable. For example, the composition may first be extruded and formed into pellets. The pellets may then be fed into a molding machine where it may be formed into any desirable shape or product. Alternatively, the composition emanating from a single melt blender may be formed into sheets or strands and subjected to post-extrusion processes such as annealing, uniaxial or biaxial orientation.

The temperature of the melt in the present process may in some aspects be maintained as low as possible in order to avoid excessive degradation of the components (e.g., the polymer in the at least one extruded polymer layer). In certain aspects, the melt temperature is maintained between about 121.1° C. (250° F.) and about 287.8° C. (550° F.), or even between about 121.1° C. (250° F.) and about 232.2 (450° F.). In some aspects, the melt processed composition exits processing equipment such as an extruder through small exit holes in a die. The resulting strands of molten resin may be cooled by passing the strands through a water bath. The cooled strands can be chopped into small pellets for packaging and further handling.

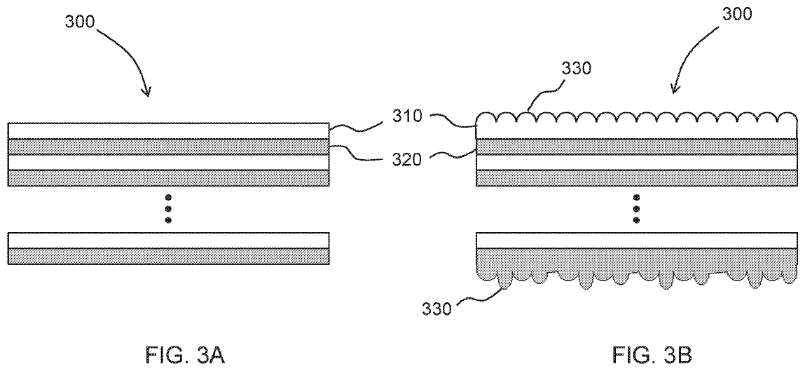

With reference to FIGS. 3A and 3B, in some aspects the quantum dot film 300 includes a plurality of extruded polymer layers 310, 320. Each of the plurality of extruded polymer layers 310, 320 includes a plurality of stabilized quantum dots as described above. The plurality of stabilized quantum dots in each of the plurality of extruded polymer layers 310, 320 may emit light having the same wavelength(s) as those in other of the extruded polymer layers or in some aspects each of the plurality of extruded polymer layers 310, 320 may include different types of stabilized quantum dots such that the stabilized quantum dots in one extruded polymer layer (e.g., 310) emit light having a wavelength that is different than the wavelength of light emitted by the stabilized quantum dots in another extruded polymer layer (e.g., 320). Thus, for example, one or more of the extruded polymer layers 310 may include stabilized quantum dots that emit green light, and one or more other extruded polymer layers 320 may include stabilized quantum dots that emit red light. As illustrated in FIG. 3B, one or more of the plurality of extruded polymer layers may include texturing 330 for modifying the optical properties of the quantum dot film 300, as desired.

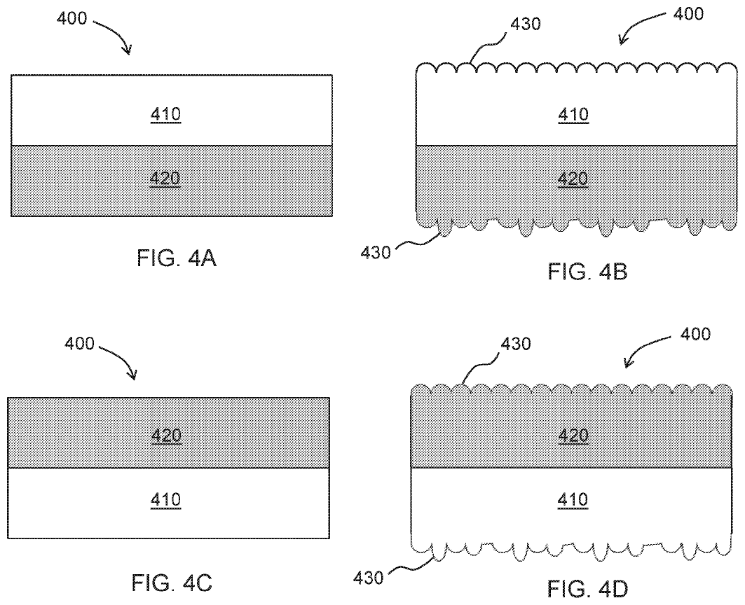

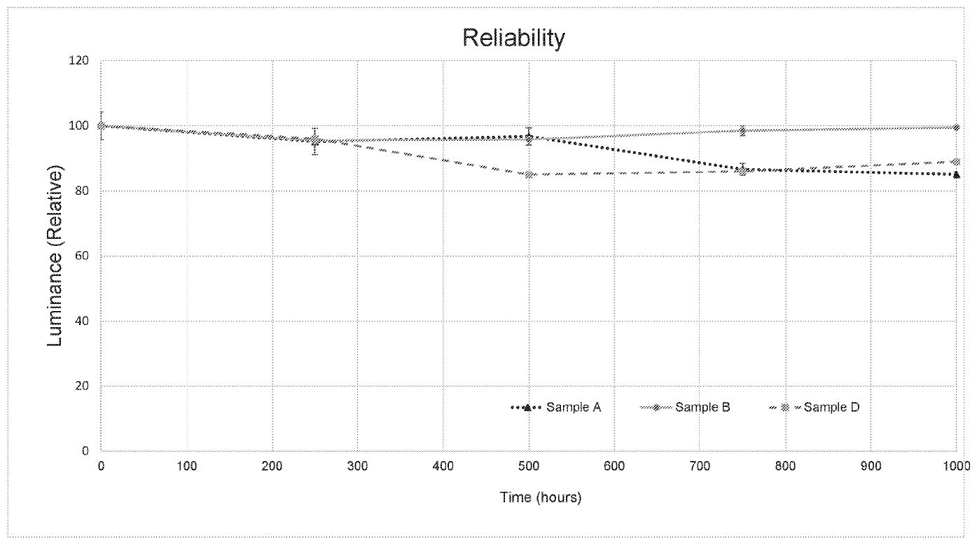

Other aspects of a multi-layer quantum dot film 400 are illustrated in FIGS. 4A-4D, including a plurality of extruded polymer layers 410, 420 with optional texturing 430 on one or more surfaces of the extruded polymer layers 410, 420. The plurality of stabilized quantum dots in each of the plurality of extruded polymer layers 410, 420 may emit light having the same wavelength(s) as those in other of the extruded polymer layers or in some aspects each of the plurality of extruded polymer layers 410, 420 may include different types of stabilized quantum dots such that the stabilized quantum dots in one extruded polymer layer (for example, 410) emit light having a wavelength that is different than the wavelength of light emitted by the stabilized quantum dots in another extruded polymer layer (for example, 420). Thus, for example, one or more of the extruded polymer layers 410 may include stabilized quantum dots that emit green light, and one or more other extruded polymer layers 420 may include stabilized quantum dots that emit red light.

In particular aspects the quantum dot film includes at least two extruded polymer layers 310, 320, 410, 420, wherein substantially all of the stabilized quantum dots in one of the extruded polymer layers emits light having a first wavelength, and substantially all of the stabilized quantum dots in another of the extruded polymer layers emits light having a second wavelength, and wherein the first wavelength is different than the second wavelength. As used herein, “substantially all of the stabilized quantum dots” means that (1) all of the stabilized quantum dots in the respective extruded polymer layer emit light having the first/second wavelength, or (2) a significant portion of the stabilized quantum dots in the respective polymer layer emit light having the first/second wavelength such that the light emitted from the stabilized quantum dots satisfies color standards for light at the respective wavelength.

Separation of different types of quantum dots (e.g., those that emit light having different colors) in extruded polymer layers 310, 320, 410, 420 as shown in FIGS. 3A-4D allows for an increase in quantum efficiency of the quantum dot film 300, 400. Quantum dots that emit light at different wavelengths are susceptible to a phenomenon called Förster Resonance Energy Transfer (FRET), also referred to as fluorescence resonance energy transfer, in which non-radiative energy is transferred from a fluorescent donor (for example, a quantum dot emitting light at a higher energy) to a lower energy acceptor (for example, a quantum dot emitting light at a lower energy) through long-range dipole-dipole interactions. FRET can occur if two particles (for example, quantum dots) are within about 20 nm of each other. In aspects of the present disclosure, FRET between quantum dots that emit light at different colors (e.g., red and green) is avoided by locating quantum dots that emit light at one color in one extruded polymer layer 310, 410 and locating quantum dots that emit light at a different color in another extruded polymer layer 320, 420.

The plurality of extruded polymer layers described herein may be extruded in any suitable process. Examples include, but are not limited to, a co-extrusion process and a multi-layer extrusion (MLE) process.

In some aspects, the quantum dot film 200, 300, 400 does not include a barrier layer such as those found in conventional quantum dot films. As a result, the quantum dot film 200, 300, 400 may be made with fewer processes, and thinner quantum dot films can be made. These improvements reduce the cost of the quantum dot film and enhance the optical properties of the quantum dot film. In particular, in the case of quantum dot films including a plurality of extruded polymer layers, the plurality of extruded polymer layers are seamless (in contrast to conventional quantum dot films including one or more barrier layers), which further enhances the optical properties of the quantum dot film because light emitted by the stabilized quantum dots is not affected as it travels from one extruded polymer layer to the other.

### Properties of Stabilized Quantum Dots

The plurality of stabilized quantum dots included in quantum dot film according to aspects of the disclosure have improved properties as compared to quantum dots included in conventional quantum dot films. The plurality of stabilized quantum dots are one or more of thermally stabilized, air stabilized, moisture stabilized and flux stabilized.

In some aspects, the plurality of stabilized quantum dots are thermally stabilized such that the quantum dot film exhibits no appreciable degradation of optical properties at a temperature of at least about 40 degrees Celsius (° C.). In further aspects, the plurality of stabilized quantum dots are thermally stabilized such that the quantum dot film exhibits no appreciable degradation of optical properties at a temperature of at least about 50° C., or at a temperature of at least about 60° C., or at a temperature of at least about 70° C., or at a temperature of at least about 80° C., or at a temperature of at least about 90° C., or at a temperature of at least about 100° C.

As used herein, “appreciable degradation of optical properties” means that, when the stabilized quantum dot is exposed to the stated condition, the emission spectra of the stabilized quantum dot either does not change or does not change to a substantial degree (e.g., the change is less than about 10%). Emission spectra of a quantum dot may be quantified by measuring the width of the Gaussian curve of the emission spectra at half of its maximum value, known as “full width at half maximum,” or FWHM. Degradation of a quantum dot under adverse conditions such as those described herein can cause its FWHM to increase and its peak wavelength to shift, resulting in a change in optical properties. Thus, in some aspects an “appreciable degradation of optical properties” may include a change in FWHM of more than about 10% or a shift in peak wavelength of more than about 10%.

In certain aspects, the plurality of stabilized quantum dots are air stabilized such that the quantum dot film exhibits no appreciable degradation of optical properties when exposed to air having a relative humidity of 95% and a temperature of 60° C. for 1000 hours.

In further aspects, the plurality of stabilized quantum dots are moisture stabilized such that the quantum dot film exhibits no appreciable degradation of optical properties when exposed to air having a relative humidity of 95% and a temperature of 60° C. for 1000 hours.

In particular aspects, the plurality of stabilized quantum dots are flux stabilized such that the quantum dot film exhibits no appreciable degradation of optical properties when exposed to an acceleration flux of 350 milliwatt per square centimeter (mW/cm²) for 100 hours.

In specific aspects, the plurality of stabilized quantum dots are flux stabilized and thermal stabilized such that the quantum dot film exhibits no appreciable degradation of optical properties when exposed for 100 hours to an acceleration flux of 350 mW/cm² in air having a temperature of 60° C.

The disclosed quantum dot film may provide certain color properties, mono-dispersity and uniform size distribution, high fluorescence efficiency, small half-width (about 25 nm to about 50 nm), low toxicity (cadmium Cd molar content may be reduced to a about 1% or less), and good stability. In specific examples, the disclosed quantum dot film may be more stable over 30% compare to non-stabilized QD in the air and moisture circumstance, and more thermal stable over 30% compare to non-stabilized QD.

### Articles of Manufacture

Aspects of the disclosure also relate to an article including the quantum dot film (or films) described herein. In some aspects the article is a display for an electronic device. The electronic device may include but is not limited to a mobile device, a tablet device, a gaming system, a handheld electronic device, a wearable device, a television, a desktop computer, or a laptop computer. The quantum dot film may in particular aspects be used in multi-layer extrusion (MLE), micro lens, prism and diffuser applications.

Various combinations of elements of this disclosure are encompassed by this disclosure, e.g., combinations of elements from dependent claims that depend upon the same independent claim.

### Aspects of the Disclosure

In various aspects, the present disclosure pertains to and includes at least the following aspects.

Aspect 1A: A quantum dot film comprising at least one extruded polymer layer, the at least one extruded polymer layer comprising a plurality of stabilized quantum dots.

Aspect 1B: A quantum dot film consisting essentially of at least one extruded polymer layer, the at least one extruded polymer layer comprising a plurality of stabilized quantum dots.

Aspect 1C: A quantum dot film consisting of at least one extruded polymer layer, the at least one extruded polymer layer comprising a plurality of stabilized quantum dots.

Aspect 2A: The quantum dot film according to any of Aspects 1A-1C, wherein each of the plurality of stabilized quantum dots comprise one or more of the following:

an encapsulation around each of the plurality of stabilized quantum dots, the encapsulation comprising an organic material or an inorganic material;

a plurality of ligands having a length of about 5 nanometers (nm) to about 200 nm;

a multi-shell structure;

a shell having a thickness of about 1 to about 20 nm; and

a concentration-gradient quantum dot.

Aspect 2B: The quantum dot film according to any of Aspects 1A-1C, wherein each of the plurality of stabilized quantum dots consist essentially of one or more of the following:

an encapsulation around each of the plurality of stabilized quantum dots, the encapsulation comprising an organic material or an inorganic material;

a plurality of ligands having a length of about 5 nanometers (nm) to about 200 nm;

a multi-shell structure;

a shell having a thickness of about 1 to about 20 nm; and

a concentration-gradient quantum dot.

Aspect 2C: The quantum dot film according to any of Aspects 1A-1C, wherein each of the plurality of stabilized quantum dots consists of one or more of the following:

an encapsulation around each of the plurality of stabilized quantum dots, the encapsulation comprising an organic material or an inorganic material;

a plurality of ligands having a length of about 5 nanometers (nm) to about 200 nm;

a multi-shell structure;

a shell having a thickness of about 1 to about 20 nm; and

a concentration-gradient quantum dot.

Aspect 2D. A quantum dot film comprising at least one extruded polymer layer, the at least one extruded polymer layer comprising a plurality of stabilized quantum dots, wherein each of the plurality of stabilized quantum dots comprise one or more of the following: an encapsulation around each of the plurality of stabilized quantum dots, the encapsulation comprising an organic material or an inorganic material; a plurality of ligands having a length of about 5 nanometers (nm) to about 200 nm; a multi-shell structure; a shell having a thickness of about 1 to about 20 nm; and a concentration-gradient quantum dot.

Aspect 3: The quantum dot film according to any of Aspects 2A-2C, wherein one or more of the plurality of stabilized quantum dots is a metal nanomaterial or an inorganic nanomaterial.

Aspect 4: The quantum dot film according to any of Aspects 1A to 3, wherein one or more of the plurality of stabilized quantum dots is a nanoparticle, a nanofiber, a nanorod, or a nanowire.

Aspect 5: The quantum dot film according to any of Aspects 1A to 4, wherein one or more of the plurality of stabilized quantum dots has a size of from about 1 nanometer (nm) to about 100 nm.

Aspect 6: The quantum dot film according to any of Aspects 1A to 5, wherein the plurality of stabilized quantum dots are thermally stabilized such that the quantum dot film exhibits no appreciable degradation of optical properties at a temperature of at least about 40 degrees Celsius (° C.).

Aspect 7: The quantum dot film according to any of Aspects to 1A to 6, wherein the plurality of stabilized quantum dots are air stabilized such that the quantum dot film exhibits no appreciable degradation of optical properties when exposed to air having a relative humidity of 95% and a temperature of 60° C. for 1000 hours.

Aspect 8: The quantum dot film according to any of Aspects to 1A to 7, wherein the plurality of stabilized quantum dots are moisture stabilized such that the quantum dot film exhibits no appreciable degradation of optical properties when exposed to air having a relative humidity of 95% and a temperature of 60° C. for 1000 hours.

Aspect 9: The quantum dot film according to any of Aspects to 1A to 8, wherein the plurality of stabilized quantum dots are flux stabilized such that the quantum dot film exhibits no appreciable degradation of optical properties when exposed to an acceleration flux of 350 milliwatt per square centimeter (mW/cm²) for 100 hours.

Aspect 10: The quantum dot film according to any of Aspects to 1A to 9, wherein the plurality of stabilized quantum dots are flux stabilized and thermal stabilized such that the quantum dot film exhibits no appreciable degradation of optical properties when exposed for 100 hours to an acceleration flux of 350 mW/cm² in air having a temperature of 60° C.

Aspect 11: The quantum dot film according to any of Aspects 1A to 10, wherein the at least one extruded polymer layer comprises a polymer selected from the group consisting of polycarbonate (PC), polyethylene terephthalate (PET), polymethyl methacrylate (PMMA), polyaryletherketones (PAEK), polybutylene terephthalate (PBT), cyclic olefin copolymer (COC), polyethylene naphthalate (PEN), poly(ether sulfone) PES, polyamide (PA), polyphthalamide (PPA), polyimides, polyolefins, polystyrene, and a combination thereof.

Aspect 12: The quantum dot film according to any of Aspects 1A to 11, wherein the at least one extruded polymer layer further comprises a scattering material.

Aspect 13: The quantum dot film according to Aspect 12, wherein the scattering material comprises titanium dioxide (TiO₂), silicon dioxide (SiO₂), aluminum oxide (Al₂O₃), zinc oxide (ZnO), zinc peroxide (ZnO₂), zirconium dioxide (ZrO₂), or a combination thereof.

Aspect 14: The quantum dot film according to any of Aspects 1A to 13, wherein the at least one extruded polymer layer further comprises one or more optional additional additives.

Aspect 15: The quantum dot film according to Aspect 14, wherein the one or more optional additional additives comprise a dispersant, a binder, a scavenger, a stabilizer or a combination thereof.

Aspect 16: The quantum dot film according to any of Aspects 1A to 15, wherein the quantum dot film comprises a plurality of extruded polymer layers and the plurality of extruded polymer layers are extruded in a co-extrusion process or a multi-layer extrusion (MLE) process.

Aspect 17: The quantum dot film according to any of Aspects 1A to 16, wherein the quantum dot film comprises at least two extruded polymer layers, wherein substantially all of the stabilized quantum dots in one of the extruded polymer layers emits light having a first wavelength, and substantially all of the stabilized quantum dots in another of the extruded polymer layers emits light having a second wavelength, and wherein the first wavelength is different than the second wavelength.

Aspect 18: The quantum dot film according to Aspect 17, wherein the first wavelength corresponds to light having a red color and the second wavelength corresponds to light having a green color.

Aspect 19: The quantum dot film according to any of Aspects 1A to 18, wherein the at least one extruded polymer layer is textured.

Aspect 20: The quantum dot film according to any of Aspects 1A to 19, wherein the quantum dot film does not include a barrier layer.

Aspect 21: An article comprising the quantum dot film according to any of Aspects 1A to 20.

Aspect 22: The article according to Aspect 21, wherein the article comprises a display for an electronic device, wherein the electronic device is a mobile device, a tablet device, a gaming system, a handheld electronic device, a wearable device, a television, a desktop computer, or a laptop computer.

Aspect 23A: A method of making a quantum dot film, comprising extruding at least one polymer layer into a film, wherein the at least one polymer layer comprises a plurality of stabilized quantum dots.

Aspect 23B: A method of making a quantum dot film, consisting essentially of extruding at least one polymer layer into a film, wherein the at least one polymer layer comprises a plurality of stabilized quantum dots.

Aspect 23C: A method of making a quantum dot film, consisting of extruding at least one polymer layer into a film, wherein the at least one polymer layer comprises a plurality of stabilized quantum dots.

Aspect 24: The method according to Aspect 23, wherein each of the plurality of stabilized quantum dots comprise one or more of the following:

an encapsulation around each of the plurality of stabilized quantum dots, the encapsulation comprising an organic material or an inorganic material;

a plurality of ligands having a length of about 5 nanometers (nm) to about 200 nm;

a multi-shell structure;

a shell having a thickness of about 1 to about 20 nm; and

a concentration-gradient quantum dot.

Aspect 25: The method according to any of Aspects 23A-24, wherein one or more of the plurality of stabilized quantum dots is a metal nanomaterial or an inorganic nanomaterial.

Aspect 26: The method according to any of Aspects 23A to 25, wherein one or more of the plurality of stabilized quantum dots is a nanoparticle, a nanofiber, a nanorod, or a nanowire.

Aspect 27: The method according to any of Aspects 23A to 26, wherein one or more of the plurality of stabilized quantum dots has a size of from about 1 nanometer (nm) to about 100 nm.

Aspect 28: The method according to any of Aspects 23A to 27, wherein the plurality of stabilized quantum dots are thermally stabilized such that the quantum dot film exhibits no appreciable degradation of optical properties at a temperature of at least about 40° C.

Aspect 29: The method according to any of Aspects to 23A to 28, wherein the plurality of stabilized quantum dots are air stabilized such that the quantum dot film exhibits no appreciable degradation of optical properties when exposed to air having a relative humidity of 95% and a temperature of 60° C. for 1000 hours.

Aspect 30: The method according to any of Aspects to 23A to 29, wherein the plurality of stabilized quantum dots are moisture stabilized such that the quantum dot film exhibits no appreciable degradation of optical properties when exposed to air having a relative humidity of 95% and a temperature of 60° C. for 1000 hours.

Aspect 31: The method according to any of Aspects to 23A to 30, wherein the plurality of stabilized quantum dots are flux stabilized such that the quantum dot film exhibits no appreciable degradation of optical properties when exposed to an acceleration flux of 350 milliwatt per square centimeter (mW/cm²) for 100 hours.

Aspect 32: The method according to any of Aspects to 23A to 31, wherein the plurality of stabilized quantum dots are flux stabilized and thermal stabilized such that the quantum dot film exhibits no appreciable degradation of optical properties when exposed for 100 hours to an acceleration flux of 350 mW/cm² in air having a temperature of 60° C.

Aspect 33: The method according to any of Aspects 23A to 32, wherein the at least one polymer layer comprises a polymer selected from the group consisting of polycarbonate (PC), polyethylene terephthalate (PET), polymethyl methacrylate (PMMA), polyaryletherketones (PAEK), polybutylene terephthalate (PBT), cyclic olefin copolymer (COC), polyethylene naphthalate (PEN), poly(ether sulfone) PES, polyphthalamide (PPA), polyimides, polyolefins, polystyrene, and a combination thereof.

Aspect 34: The method according to any of Aspects 23A to 33, wherein the at least one polymer layer further comprises a scattering material.

Aspect 35: The method according to Aspect 34, wherein the scattering material comprises titanium dioxide (TiO₂), silicon dioxide (SiO₂), aluminum oxide (Al₂O₃), zinc oxide (ZnO), zinc peroxide (ZnO₂), zirconium dioxide (ZrO₂), or a combination thereof.

Aspect 36: The method according to any of Aspects 23A to 35, wherein the at least one polymer layer further comprises one or more optional additional additives.

Aspect 37: The method according to Aspect 36, wherein the one or more optional additional additives comprise a dispersant, a binder, a scavenger, a stabilizer or a combination thereof.

Aspect 38: The method according to any of Aspects 23A to 37, wherein the step of extruding at least one polymer layer into a film is performed using a co-extrusion process or a multi-layer extrusion (MLE) process.

Aspect 39: The method according to any of Aspects 23A to 37, comprising extruding at least two polymer layers into a film, wherein substantially all of the stabilized quantum dots in one of the polymer layers emits light having a first wavelength, and substantially all of the stabilized quantum dots in another of the polymer layers emits light having a second wavelength, and wherein the first wavelength is different than the second wavelength.

Aspect 40: The method according to Aspect 38, wherein the first wavelength corresponds to light having a red color and the second wavelength corresponds to light having a green color.

Aspect 41: The method according to any of Aspects 23A to 40, further comprising texturing the at least one polymer layer.

Aspect 42: The method according to any of Aspects 23A to 41, wherein the quantum dot film does not include a barrier layer.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric. Unless indicated otherwise, percentages referring to composition are in terms of wt %.

There are numerous variations and combinations of reaction conditions, e.g., component concentrations, desired solvents, solvent mixtures, temperatures, pressures and other reaction ranges and conditions that can be used to optimize the product purity and yield obtained from the described process. Only reasonable and routine experimentation will be required to optimize such process conditions.

### Example 1

Samples A through D were measured under the following conditions: Optical measurement system: Sample: 10 cm×10 cm for three pieces, 3 points measurement; using the light source: Kindle fire (Luminance of bare Blue BLU: 50˜60 cd/m²); with the spectrophotometer: Topcon SR-3AR; and at hydro aging conditions of: 60° C./95% relative humidity (RH %). Reliability tests included the luminance drop ratio, color point, peak wavelength (PWL) and full width half maximum (FWHM) and edge ingress.

Sample A was a stable QD embedded extrusion film without a barrier film; Sample B, a stable QD embedded extrusion film without a barrier film; Sample C, a commercial grade QD embedded solvent casting file with barrier film; and, Sample D, a commercial grade solvent casting film with barrier film. Further properties and structures of each sample is summarized in Table 1.

TABLE 1
Thickness and Film structure of Samples A through D

| | Total Thickness (um) | Film structure (um) |
|---|---|---|
| A | 243 | QD extrusion film (243) |
| B | 219 | QD extrusion film (219) |
| C | 360 | Upperbarrier (100)/QD matrix (160)/ |
| | | bottom barrier (100) |
| D | 310 | Upperbarrier (105)/QD matrix(100) |

Samples A through D were observed for their relative luminance at test conditions of 60° C. and 95% RH as shown in in FIG. 5. The luminance drop ratio (Luminance after hydro aging: initial luminance, L/L₀) at 1000 hours was also obtained. Results indicated that the stable QD embedded extrusion film are stable at 1000 hours.

Values for color point were also obtained and are presented in Table 2, where delta x (Δx) is less than or equal to ±0.01 and Δy is less than or equal to 0.01. X and y refer to color points from CIE 1931 color space/chromaticity coordinates. X, Y color point may indicate QD material's color stability under any circumstances.

TABLE 2
Color point for Samples A-D

| | | A | | B | | C | | D | |
|---|---|---|---|---|---|---|---|---|---|
| | | x | y | x | y | x | y | x | y |
| 0 | hr | 0.163 | 0.078 | 0.198 | 0.046 | 0.182 | 0.109 | 0.189 | 0.106 |
| 250 | hr | 0.164 | 0.076 | 0.195 | 0.045 | 0.183 | 0.111 | 0.188 | 0.106 |
| 500 | hr | 0.165 | 0.081 | 0.201 | 0.047 | 0.184 | 0.110 | 0.189 | 0.106 |
| 750 | hr | 0.164 | 0.071 | 0.199 | 0.047 | 0.185 | 0.114 | 0.189 | 0.105 |
| 1000 | hr | 0.163 | 0.069 | 0.199 | 0.047 | 0.185 | 0.114 | 0.189 | 0.105 |

The values observed for color point indicate that Samples A and B (stable QD embedded extrusion film without barrier film) is stable at 1000 hours.

Samples A through D were also tested for PWL and FWHM and the values are presented in Table 3.

TABLE 3
PWL and FWHM for Samples A-D

| | | A | | B | | C | | D | |
|---|---|---|---|---|---|---|---|---|---|
| | | PWL | FWHM | PWL | FWHM | PWL | FWHM | PWL | FWHM |
| 0 | hr | 537.9 | 33.5 | 631.0 | 30.7 | 525.8 | 29.8 | 622.1 | 36.2 |
| 250 | hr | 539.8 | 34.3 | 631.4 | 30.5 | 526.1 | 29.9 | 622.1 | 36.1 |
| 500 | hr | 539.2 | 34.1 | 630.9 | 30.3 | 525.9 | 30.0 | 621.9 | 36.0 |
| 750 | hr | 539.8 | 34.7 | 631.5 | 30.4 | 526.0 | 29.8 | 621.9 | 36.1 |
| 1000 | hr | 539.5 | 35.2 | 631.3 | 30.6 | 526.0 | 29.9 | 621.9 | 36.1 |

The values observed for PWL and FWHM also indicate that Samples A and B is stable at 1000 hours.

Edge ingress (in mm) was observed from 250 hours to 1000 hours on samples under 60° C. and 95% RH conditions with hydro aging acceleration in Samples C and D. Table 3 summarizes the edge ingress observed. As noted, Samples A and B did not exhibit any edge ingress over the time frame.

TABLE 3
Edge ingress of Samples A-D

| | Edge ingress (millimeters, mm) | | | | |
|---|---|---|---|---|---|
| | 0 hr | 250 hr | 500 hr | 750 hr | 1000 hr |
| A | No edge | No edge | No edge | No edge | No edge |
| | ingress | ingress | ingress | ingress | ingress |
| B | No edge | No edge | No edge | No edge | No edge |
| | ingress | ingress | ingress | ingress | ingress |
| C | No edge | 0.75 | 0.75 | 0.76 | 0.76 |
| | ingress | | | | |
| D | No edge | 0.82 | 0.83 | 0.92 | 0.96 |
| | ingress | | | | |

Table 4 summarizes physical properties and characteristics observed for the disclosed film.

TABLE 4
Physical characteristics.

| | Unit | Specification | Test Method |
|---|---|---|---|
| Density | g/cm² | | |
| Elongation | % | 108/80 | ASTM D882: 0.5 |
| (MD/TD) | | | (mm/mm)*min strain rate |
| Heat shrinkage | % | 0.15/0.009 | TMA: 2° C./min, 85° C. |
| (MD/TD) | | | 30 min, 25° C. reference, |
| | | | initial RH < 20%, 24 mm length |
| Edge Ingress | mm | 1.0 | Ruler |
| | | Maximum | |
| Edge | mm | 1.0 | Ruler |
| Delamination | | Maximum | |

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above detailed description includes references to the accompanying drawings, which form a part of the detailed description. The drawings show, by illustration, examples of how the disclosure may be practiced. Such examples may include elements in addition to those shown or described or may include only the elements shown or described. In this document, the terms “a” or “an” are used, to include one or more than one, independent of any other instances or usages of “at least one” or “one or more.” The term “or” is used to refer to a nonexclusive or. The terms “including” and “in which” are used as the plain-English equivalents of the respective terms “comprising” and “wherein.” Also, in the claims, the term “comprising” is open-ended. Moreover, in the claims, the terms “first,” “second,” and “third,” etc. are used merely as labels, and are not intended to impose numerical requirements on their objects. The Abstract is provided to allow the reader to quickly ascertain the nature of the technical disclosure and is not to be used to interpret or limit the claims. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed embodiment, the terms “substantially” and “about” may be substituted within “within [a percentage] of” what is specified, where the percentage includes 0.1, 1, 5, and/or 10 percent.

The above description is intended to be illustrative, and not restrictive. For example, the above-described examples (or one or more aspects thereof) may be used in combination with each other. Other aspects can be used, such as by one of ordinary skill in the art upon reviewing the above description. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed aspect. Thus, the following claims are hereby incorporated into the Detailed Description as examples or aspects, with each claim standing on its own as a separate aspect, and it is contemplated that such aspects can be combined with each other in various combinations or permutations. The scope of the disclosure should be determined with reference to the appended claims, along with the full scope of equivalents to which such claims are entitled.

1-20. (canceled)

21. A quantum dot film comprising a plurality of extruded polymer layers, wherein at least one of the extruded polymer layers comprises a plurality of stabilized quantum dots, and wherein one or more of the plurality of stabilized quantum dots is a metal nanomaterial or an inorganic nanomaterial.

22. The quantum dot film according to claim 21, wherein each of the plurality of stabilized quantum dots comprise one or more of the following:
an encapsulation around each of the plurality of stabilized quantum dots, the encapsulation comprising an organic material or an inorganic material;
a plurality of ligands having a length of 5 nanometers (nm) to 200 nm;
a multi-shell structure;
a shell having a thickness of 1 to 20 nm; and
a concentration-gradient quantum dot.

23. The quantum dot film according to claim 21, wherein one or more of the plurality of stabilized quantum dots is a nanoparticle, a nanofiber, a nanorod, or a nanowire.

24. The quantum dot film according to claim 21, wherein one or more of the plurality of stabilized quantum dots has a size of from 1 nanometer (nm) to 100 nm.

25. The quantum dot film according to claim 21, wherein the plurality of stabilized quantum dots are thermally stabilized such that the quantum dot film exhibits no appreciable degradation of optical properties at a temperature of at least 40 degrees Celsius (° C.).

26. The quantum dot film according to claim 21, wherein the plurality of stabilized quantum dots are air stabilized such that the quantum dot film exhibits no appreciable degradation of optical properties when exposed to air having a relative humidity of 95% and a temperature of 60° C. for 1000 hours.

27. The quantum dot film according to claim 21, wherein the plurality of stabilized quantum dots are moisture stabilized such that the quantum dot film exhibits no appreciable degradation of optical properties when exposed to air having a relative humidity of 95% and a temperature of 60° C. for 1000 hours.

28. The quantum dot film according to claim 21, wherein the plurality of stabilized quantum dots are flux stabilized such that the quantum dot film exhibits no appreciable degradation of optical properties when exposed to an acceleration flux of 350 milliwatt per square centimeter (mW/cm²) for 100 hours.

29. The quantum dot film according to claim 21, wherein the plurality of stabilized quantum dots are flux stabilized and thermal stabilized such that the quantum dot film exhibits no appreciable degradation of optical properties when exposed for 100 hours to an acceleration flux of 350 mW/cm² in air having a temperature of 60° C.

30. The quantum dot film according to claim 21, wherein at least one of the extruded polymer layers comprises a polymer selected from the group consisting of polycarbonate (PC), polyethylene terephthalate (PET), polymethyl methacrylate (PMMA), polyaryletherketones (PAEK), polybutylene terephthalate (PBT), cyclic olefin copolymer (COC), polyethylene naphthalate (PEN), poly(ether sulfone) PES, polyamide (PA), polyphthalamide (PPA), polyimides, polyolefins, polystyrene, and a combination thereof.

31. The quantum dot film according to claim 21, wherein the at least one of the extruded polymer layers comprising the plurality of stabilized quantum dots further comprises a scattering material.

32. The quantum dot film according to claim 31, wherein the scattering material comprises titanium dioxide (TiO₂), silicon dioxide (SiO₂), aluminum oxide (Al₂O₃), zinc oxide (ZnO), zinc peroxide (ZnO₂), zirconium dioxide (ZrO₂), or a combination thereof.

33. The quantum dot film according to claim 21, wherein the at least one of the extruded polymer layers comprising the plurality of stabilized quantum dots further comprises one or more optional additional additives, the one or more optional additional additives comprising a dispersant, a binder, a scavenger, a stabilizer or a combination thereof.

34. The quantum dot film according to claim 21, wherein the plurality of extruded polymer layers are extruded in a co-extrusion process or a multi-layer extrusion (MLE) process.

35. The quantum dot film according to claim 21, wherein the quantum dot film comprises at least two extruded polymer layers comprising stabilized quantum dots, wherein substantially all of the stabilized quantum dots in one of the extruded polymer layers emits light having a first wavelength, and substantially all of the stabilized quantum dots in another of the extruded polymer layers emits light having a second wavelength, and wherein the first wavelength is different than the second wavelength.

36. The quantum dot film according to claim 35, wherein the first wavelength corresponds to light having a red color and the second wavelength corresponds to light having a green color.

37. The quantum dot film according to claim 21, wherein at least one of the extruded polymer layers is textured.

38. The quantum dot film according to claim 21, wherein the quantum dot film does not include a barrier layer.

39. An article comprising the quantum dot film according to claim 21, wherein the article comprises a display for an electronic device, wherein the electronic device is a mobile device, a tablet device, a gaming system, a handheld electronic device, a wearable device, a television, a desktop computer, or a laptop computer.
